(19) United States
(12) Patent Application Publication
(10) Pub. No.: US 2009/0160057 A1
(43) Pub. Date: Jun. 25, 2009

(54) Semiconductor device and method of manufacturing the same

(76) Inventor: Yukimasa Minami, Chiba-shi (JP)

Correspondence Address: BRUCE L. ADAMS, ESQ;ADAMS & WILKS, SUITE 1231, 17 BATTERY PLACE, NEW YORK, NY, 10004, US

(21) Appl. No.: 12/315,632

(22) Filed: Dec. 4, 2008

(30) Foreign Application Priority Data
Dec. 13, 2007 (JP) 2007-321469

(51) Int. Cl. H01L 23/532; H01L 21/283

(52) U.S. Cl. 257/751; 438/607; 257/E23.159; 257/E21.159

(57) ABSTRACT

A semiconductor device is provided in which penetration of a metal into a high impurity-doped active region from a side wall portion of a contact hole is prevented by reducing an aspect ratio to improve coverage of a titanium nitride film for the side wall portion of the contact hole, and in which increase in current consumption is eliminated. In a semiconductor device including an interlayer insulating film formed on a silicon substrate, and a interconnection formed of a barrier metal film and an aluminum alloy film and connected to the silicon substrate through a contact hole of the interlayer insulating film, a low-concentration impurity layer is epitaxially grown on a bottom surface of the contact hole, whereby the aspect ratio is reduced to improve coverage of the titanium nitride film for the side wall portion of the contact hole, and penetration of the metal into the high impurity-doped active region from the side wall portion of the contact hole is prevented.

### BACKGROUND OF THE INVENTION

1. Field of the Invention

The present invention relates to a metal structure in a contact hole of a semiconductor device.

2. Description of the Related Art

A pure aluminum interconnection has been used as an interconnecting metal of a semiconductor device for a long time. However, it is known that pure aluminum is prone to react with silicon of a substrate, such reaction occurs even at low temperature, the pure aluminum and the silicon react with each other at a portion where a silicon substrate and the pure aluminum interconnection contact each other, and the silicon of the substrate is diffused into the aluminum, whereby a pit is formed in the substrate, and the pit causes leakage. Accordingly Al—Si alloy, in which approximately 1% silicon is added into the aluminum in advance to saturate the diffusion of silicon to prevent the diffusion of the silicon in the substrate into the aluminum, has been used as an interconnecting material.

FIG. 2 illustrates a schematic cross-sectional view of a contact hole portion of a conventional semiconductor device. An interlayer insulating film 103 such as an SiO₂ film, a PSG film and a BPSG film is formed on a surface of a silicon substrate on which a semiconductor element is formed. A contact hole 104 is formed in the interlayer insulating film 103, and in the contact hole 104, an aluminum alloy interconnection 108 made of Al—Si, Al—Si—Cu or the like contacts with a silicon substrate 101. However, even in the contact of the aluminum alloy interconnection made of Al—Si, Al—Si—Cu or the like with the silicon substrate, a problem has occurred such that the silicon in the substrate is diffused into the aluminum, and that a pit-like portion in which the aluminum seems to penetrate the silicon substrate is generated, whereby current consumption is increased.

Countermeasures against this problem include further increase in amount of the silicon added to the aluminum. Excessive addition of silicon, however, causes failure in which the silicon in the aluminum interconnection precipitates at the contact portion owing to a heat cycle after interconnection formation. Specifically, the silicon added into the aluminum repeats the diffusion into the aluminum and the precipitation owing to the heat cycle, and a part of the silicon grows on the silicon substrate in the contact hole portion. In a large diameter contact hole the precipitation of the silicon does not affect resistance of the contact portion very much. However, if a size of an opening of the contact portion is reduced as small as approximately 1 μm², then there occurs a problem that the contact resistance increases owing to the precipitated silicon.

Then, in recent years, a titanium nitride film having high barrier property has been formed between the aluminum alloy interconnection made of Al—Si, Al—Si—Cu or the like and the silicon substrate, whereby improvement has been made in prevention of the penetration of the aluminum (for example, refer to JP 05-291559 A).

Though the improvement regarding the barrier property has been made in recent years by forming a metal film, such as the titanium nitride film, having a high barrier property after the formation of the contact hole in order to prevent the penetration of the metal, the following problem has occurred. Specifically, an increasing aspect ratio of the contact portion causes bad coverage of the titanium nitride film formed on a side wall portion of the contact hole compared to that of the titanium nitride film formed on a bottom surface of the contact hole, permitting penetration of the metal from the side wall portion of the contact hole, in which a thickness of the titanium nitride film is reduced, which causes generation of the pit-like portion in a high impurity-doped active region below the contact hole, and increase in the current consumption.

### SUMMARY OF THE INVENTION

The present invention has been made in view of the above-mentioned points. It is therefore an object of the present invention to provide a semiconductor device, in which the aspect ratio is reduced to improve the coverage of the titanium nitride film for the side wall portion of the contact hole, whereby the penetration of the metal into the high impurity-doped active region from the side wall portion of the contact hole is prevented, and the increase of the current consumption is eliminated.

In order to solve the above-mentioned problems, the present invention employs the following means.

There is provided a semiconductor device, including: an interlayer insulating film formed on a silicon substrate; a interconnection formed of a barrier metal film and an aluminum alloy film and connected to the silicon substrate through a contact hole of the interlayer insulating film; and a monocrystalline impurity layer of the same conductivity type as a conductivity type of a high impurity-doped active region located below the contact hole, in which the monocrystalline impurity layer is located on a bottom surface of the contact hole.

Further, there is provided a semiconductor device, including: an interlayer insulating film formed on a silicon substrate; a interconnection formed of a barrier metal film and an aluminum alloy film and connected to the silicon substrate through a contact hole of the interlayer insulating film; and a monocrystalline impurity layer of the same conductivity type as a conductivity type of a high impurity-doped active region located below the contact hole, in which the monocrystalline impurity layer fills an inside of the contact hole.

Further, there is provided a method of manufacturing a semiconductor device, including: forming an interlayer insulating film on a silicon substrate including a high impurity-doped active region, and forming a contact hole in the interlayer insulating film located above the high impurity-doped active region; forming a monocrystalline impurity layer of the same conductivity type as a conductivity type of the high impurity-doped active region in an inside of the contact hole by an epitaxial method; and depositing a barrier metal film and an aluminum alloy film on the monocrystalline impurity layer and the interlayer insulating film to form a interconnection.

As described above, in the present invention, in the layered metal structure of the semiconductor device, formation of the low-concentration impurity layer epitaxially grown from the high impurity-doped active region in the inside of the contact hole enables the reduction in the aspect ratio, and the improvement in the coverage of the titanium nitride film for the side wall portion of the contact hole, which permit prevention of the penetration of the metal into the high impurity-doped active region from the side wall portion of the contact hole, whereby giving a higher barrier property effect. The present invention eliminates the increase of the current consumption.

### BRIEF DESCRIPTION OF THE DRAWINGS

In the accompanying drawings:

FIG. 1 is a schematic cross-sectional view illustrating an embodiment of a semiconductor device of the present invention; and

FIG. 2 is a schematic cross-sectional view of a conventional semiconductor device.

### DETAILED DESCRIPTION OF THE PREFERRED EMBODIMENT

A description is made below of an embodiment of the present invention based on the drawing.

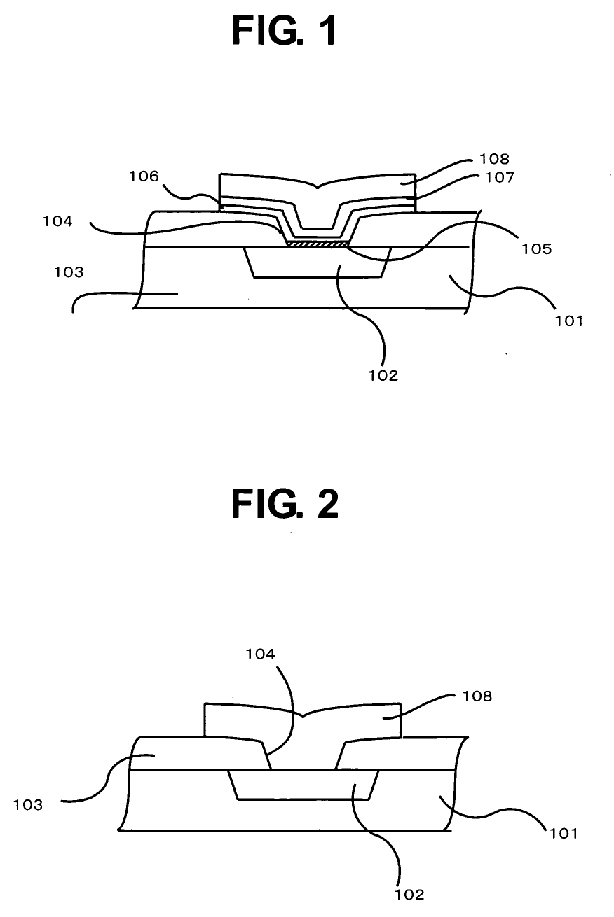

FIG. 1 illustrates an embodiment having a metal wiring structure in which aluminum in an aluminum alloy layer cannot invade an active region in a silicon substrate from a side wall portion of a contact hole. On a surface of a silicon substrate 101 on which a semiconductor element is formed, an interlayer insulating film 103 in which films such as SiO₂ films, TEOS films and BPSG films are laminated on one another is formed. A contact hole 104 is formed in the interlayer insulating film 103.

A monocrystalline impurity layer 105 is formed in an inside of the contact hole 104 by epitaxially growing a high impurity-doped active region 102, and through the contact hole 104, a titanium film 106 contacts with the silicon substrate 101 including the monocrystalline impurity layer 105. Here, a concentration of the high impurity-doped active region 102 to be epitaxially grown ranges approximately from 1E21 to 3E21 cm⁻³. Further, the structure includes a titanium nitride film 107 formed on the titanium film 106, and an aluminum alloy interconnection 108 provided on the titanium nitride film 107.

Titanium is deposited to a thickness ranging approximately from 300 to 500 Å by, for example, sputtering or the CVD method, and the resulting titanium film 106 is applied to enhance the adhesion strength between the subsequently-deposited titanium nitride film 107, and the side and bottom surface of the contact hole. The titanium nitride film 107 with a thickness ranging approximately from 1,000 to 1,400 Å is formed thereupon as a barrier metal layer for preventing penetration of the aluminum in the aluminum alloy interconnection 108 to be formed in the subsequent step into the high impurity-doped active region 102.

A weak region is, however, generated in a so to speak penetration prevention film for the aluminum into the high impurity-doped active region 102 located below the contact hole 104 since the thickness of the titanium nitride film 107 formed in the contact hole 104 has a tendency that the bottom surface of the contact hole 104 becomes thick, and that the side wall portion thereof becomes thin when the aspect ratio of the contact hole 104 increases. As the monocrystalline impurity layer 105 formed by epitaxially growing the high impurity-doped active region 102 in the inside of the contact hole 104 becomes thicker, a more effect is brought that the aspect ratio of the contact hole is reduced to improve coverage of the titanium nitride film for the side wall portion of the contact hole. It is also possible to eliminate a step difference between a surface of the monocrystalline impurity layer 105 and a surface of the interlayer insulating film 103 in such a manner that the monocrystalline impurity layer 105 is grown sufficiently by the epitaxial method and the inside of the contact hole is fully filled therewith. Note that the aluminum alloy interconnection 108 is made of a interconnection material such as an Al—Si alloy containing 1% of silicon, an Al—Si—Cu alloy containing 1% of silicon and 0.5% of copper, or tungsten, and a thickness of the aluminum alloy interconnection 108 ranges approximately from 300 to 8,000 Å.

As described above, the monocrystalline impurity layer is grown in the contact hole by the epitaxial method, whereby the aspect ratio of the contact hole may be controlled freely. In such a way, the contact hole coverage property of the barrier metal layer deposited on the surface of the monocrystalline impurity layer may be improved. Specifically, the invasion of the metal into the high impurity-doped active region from the side wall portion of the contact hole may be prevented, whereby the improvement may be made so as to prevent the penetration of the aluminum, and the increase of the current consumption may be eliminated completely.

What is claimed is:

1. A semiconductor device, comprising:
an interlayer insulating film formed on a silicon substrate;
an interconnection formed of a barrier metal film and an aluminum alloy film and connected to the silicon substrate through a contact hole of the interlayer insulating film; and
a monocrystalline impurity layer having the same conductivity type as a conductivity type of a high impurity-doped active region located below the contact hole, the monocrystalline impurity layer being located on a bottom surface of the contact hole.

2. A semiconductor device, comprising:
an interlayer insulating film formed on a silicon substrate;
a interconnection formed of a barrier metal film and an aluminum alloy film and connected to the silicon substrate through a contact hole of the interlayer insulating film; and
a monocrystalline impurity layer of the same conductivity type as a conductivity type of a high impurity-doped active region located below the contact hole, the monocrystalline impurity layer filling an inside of the contact hole.

3. A method of manufacturing a semiconductor device, comprising the steps of:
forming an interlayer insulating film on a silicon substrate including a high impurity-doped active region,
forming a contact hole in the interlayer insulating film located above the high impurity-doped active region;
forming a monocrystalline impurity layer of the same conductivity type as a conductivity type of the high impurity-doped active region in an inside of the contact hole by an epitaxial method; and
depositing a barrier metal film and an aluminum alloy film on the monocrystalline impurity layer and the interlayer insulating film to form an interconnection.
